(19) United States
(12) Patent Application Publication
(10) Pub. No.: US 2024/0282736 A1
(43) Pub. Date: Aug. 22, 2024

(54) SEMICONDUCTOR DEVICE AND METHOD OF MANUFACTURING THE SAME

(71) Applicant: Japan Display Inc., Tokyo (JP)

(72) Inventors: Yoichi KAMIJO, Tokyo (JP); Yoshikatsu IMAZEKI, Tokyo (JP); Shuichi OSAWA, Tokyo (JP); Koichi MIYASAKA, Tokyo (JP); Yoshifumi KAMEI, Tokyo (JP)

(73) Assignee: Japan Display Inc., Tokyo (JP)

(21) Appl. No.: 18/442,484

(22) Filed: Feb. 15, 2024

(30) Foreign Application Priority Data
Feb. 21, 2023 (JP) 2023-025284

(51) Int. Cl. H01L 23/00; H01L 25/16; H01L 27/12

(52) U.S. Cl. CPC H01L 24/13; H01L 24/05; H01L 24/16; H01L 25/167; H01L 27/124; H01L 24/81; H01L 2224/05008; H01L 2224/05166; H01L 2224/05548; H01L 2224/05567; H01L 2224/05624; H01L 2224/13012; H01L 2224/13014; H01L 2224/13021; H01L 2224/13078; H01L 2224/13082; H01L 2224/13111; H01L 2224/13147; H01L 2224/13155; H01L 2224/16013; H01L 2224/16052; H01L 2224/16145; H01L 2224/81815; H01L 2924/12041; H01L 2924/1426

(57) ABSTRACT

Performance of an electronic apparatus is improved. A display apparatus includes: a substrate; a wiring arranged on the substrate; an insulating layer being an inorganic insulating layer made of an inorganic material and covering the wiring; and a bump electrode being connected to the wiring and protruding from the insulating layer. The bump electrode includes: a first conductor portion being made of a first metal material and being connected to the wiring; and a second conductor portion being made of solder containing tin and being arranged on the first conductor portion. The first conductor portion includes: a first portion being connected to the wiring at a position overlapping a first opening formed in the insulating layer; and a second portion separating from the first portion and being connected to the wiring at a position overlapping a second opening formed in the insulating layer.

### CROSS-REFERENCE TO RELATED APPLICATION

The present application claims priority to Japanese Patent Application No. 2023-025284 filed on Feb. 21, 2023, the disclosure of which is incorporated herein by reference.

### TECHNICAL FIELD OF THE INVENTION

The present invention relates to an electronic apparatus.

### BACKGROUND OF THE INVENTION

There are electronic apparatuses each including an electronic component mounted on a plurality of electrodes arranged on a substrate. For example, Japanese Patent Application Laid-Open Publication No. 2014-197619 (Patent Document 1) describes an electronic apparatus including a Light Emitting Diode (LED) element mounted on a plurality of electrodes arranged on a substrate.

### SUMMARY OF THE INVENTION

In a case of an electronic apparatus including an electronic component mounted on a terminal formed on a substrate, a bump electrode may be formed on the substrate in some cases in order to facilitate connection between an electrode of the electronic component and the terminal on the substrate. According to studies made by the inventors of the present application, from observation for the electronic apparatus provided after the mounting of the electronic component, it has been found out that voids are formed between the bump electrode and the electrode of the electronic component.

An object of the present invention is to provide a technique of improving a performance of an electronic apparatus.

An electronic apparatus according to one embodiment includes: a first substrate; a first wiring arranged on the first substrate; a first insulating layer being an inorganic insulating layer made of an inorganic material and covering the first wiring; and a first bump electrode being connected to the first wiring and protruding from the first insulating layer. The first bump electrode includes: a first conductor portion being made of a first metal material and being connected to the first wiring; and a second conductor portion being made of solder containing tin and being arranged on the first conductor portion. The first conductor portion includes: a first portion being connected to the first wiring at a position overlapping a first opening formed in the first insulating layer; and a second portion separating from the first portion and being connected to the first wiring at a position overlapping a second opening formed in the first insulating layer.

An electronic apparatus according to another embodiment includes: a first substrate; a first wiring arranged on the first substrate; a first insulating layer being an inorganic insulating layer made of an inorganic material and covering the first wiring; and a first bump electrode being connected to the first wiring and protruding from the first insulating layer. The first bump electrode includes: a first conductor portion being made of a first metal material and being connected to the first wiring; and a second conductor portion being made of solder containing tin and being arranged on the first conductor portion. The first conductor portion includes: a first portion being connected to the first wiring in a first region of a first opening formed in the first insulating layer; and a second portion separating from the first portion and being connected to the first wiring in a second region of the first opening.

### BRIEF DESCRIPTIONS OF THE DRAWINGS

FIG. 1 is a plan view showing a configuration example of a micro LED display apparatus according to one embodiment of an electronic apparatus.

FIG. 2 is a circuit diagram showing a configuration example of a circuit in periphery of a pixel shown in FIG. 1.

FIG. 3 is a perspective enlarged plan view showing an example of a peripheral structure of an LED element arranged in each of a plurality of pixels of the display apparatus shown in FIG. 1.

FIG. 4 is an enlarged cross-sectional view taken along a line A-A of FIG. 3.

FIG. 5 is an enlarged plan view showing a state before mounting of a LED element shown in FIG. 3.

FIG. 6 is an enlarged cross-sectional view taken along a line B-B of FIG. 5.

FIG. 7 is an enlarged cross-sectional view of vicinity of a connection interface between a wiring and a bump electrode shown in FIG. 4.

FIG. 8 is a perspective enlarged plan view showing planar positional relation among a conductor portion containing copper, a wiring and an opening formed in an insulating layer in the bump electrode shown in FIG. 7.

FIG. 9 is an enlarged cross-sectional view of vicinity of a connection interface between a wiring and a bump electrode shown in FIG. 6.

FIG. 10 is a perspective enlarged plan view showing planar positional relation among a conductor portion made of solder, a wiring and an opening formed in an insulating layer in the bump electrode shown in FIG. 9.

FIG. 11 is an enlarged cross-sectional view showing a study example relative to FIG. 9.

FIG. 12 is a perspective enlarged plan view showing a modification example relative to FIG. 10.

FIG. 13 is a perspective enlarged plan view showing another modification example relative to FIG. 10.

FIG. 14 is an enlarged cross-sectional view taken along a line C-C of FIG. 13.

FIG. 15 is a perspective enlarged plan view showing a connection state between an anode electrode of the LED element and the bump electrode shown in FIGS. 13 and 14.

FIG. 16 is an explanatory diagram showing an example of a step flow of a method of manufacturing a display apparatus according to one embodiment of the electronic apparatus.

FIG. 17 is an enlarged cross-sectional view showing a modification example relative to FIG. 4.

FIG. 18 is a perspective enlarged plan view showing periphery of a bump electrode in a state before mounting of a LED element shown in FIG. 7.

FIG. 19 is an enlarged cross-sectional view taken along a line D-D of FIG. 18.

FIG. 20 is a perspective enlarged plan view showing a modification example relative to FIG. 18.

FIG. 21 is an enlarged cross-sectional view taken along a line E-E of FIG. 20.

FIG. 22 is a perspective enlarged plan view showing a connection state between an anode electrode of the LED element and the bump electrode shown in FIGS. 20 and 21.

### DESCRIPTIONS OF THE PREFERRED EMBODIMENTS

Hereinafter, each embodiment of the present invention will be described with reference to the accompanying drawings. Note that disclosure shows only one example, and appropriate modification with keeping the idea of the present invention which can be easily anticipated by those who are skilled in the art is obviously within the scope of the present invention. Also, in order to make the description clear, a width, a thickness, a shape, and others of each portion in the drawings are schematically illustrated more than those in an actual aspect in some cases. However, the illustration is only one example, and does not limit the interpretation of the present invention. In the present specification and each drawing, similar elements to those described earlier for the already-described drawings are denoted with the same or similar reference characters, and detailed description for them is appropriately omitted in some cases.

In the following embodiments, as an example of an electronic apparatus including an arranged bump electrode array used for mounting a plurality of electronic components, a micro LED display apparatus on which a plurality of micro LED elements are mounted and a bump electrode array before the mounting of the micro LED elements will be exemplified and explained.

### <Electronic Apparatus>

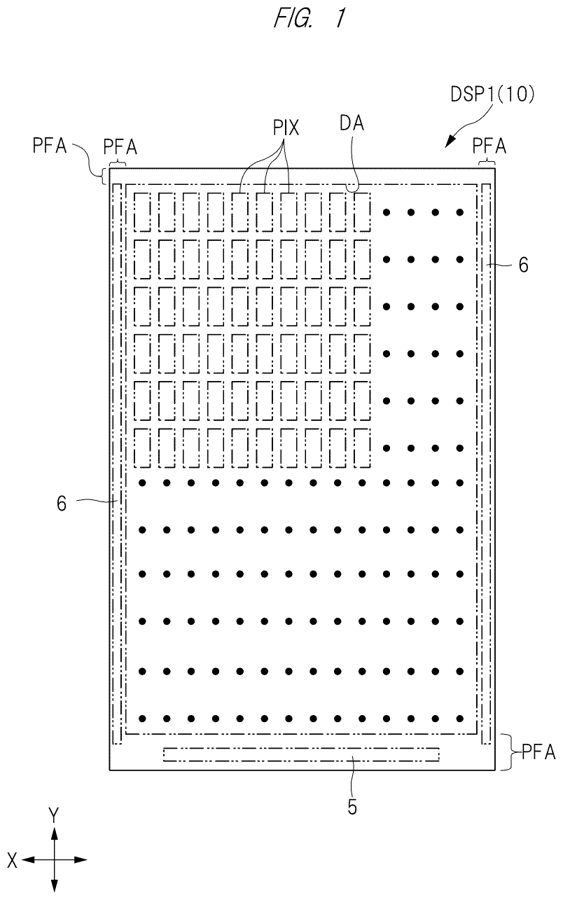

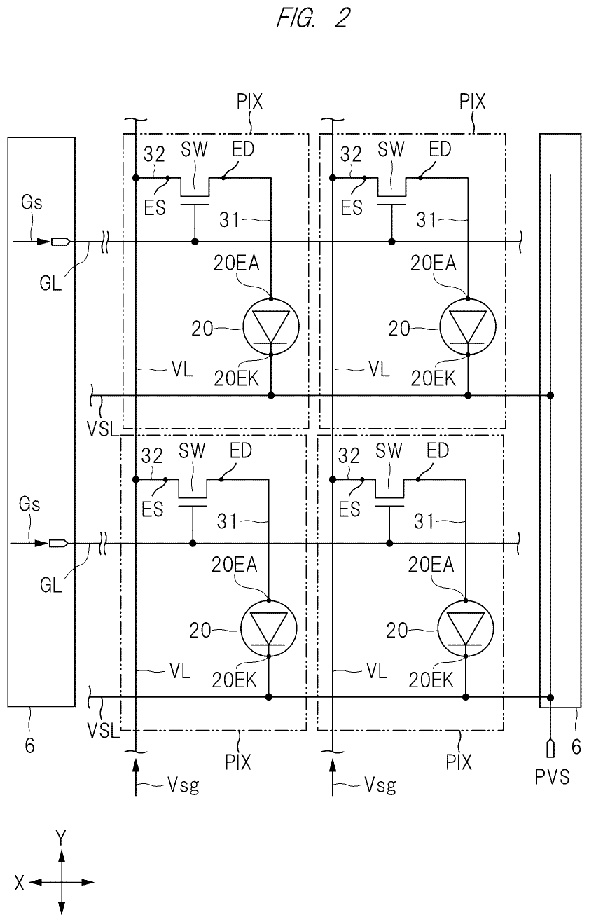

First, a configuration example of the micro LED display apparatus that is the electronic apparatus of the present embodiment will be explained. FIG. 1 is a plan view showing a configuration example of the micro LED display apparatus according to one embodiment of the electronic apparatus. In FIG. 1, each of a border between a display region DA and a peripheral region PFA, a controller circuit 5, a driver circuit 6 and a plurality of pixels PIX is illustrated with a dashed double-dotted line. FIG. 2 is a circuit diagram showing a configuration example of a circuit in periphery of a pixel shown in FIG. 1.

As shown in FIG. 1, a display apparatus DSP1 of the present embodiment includes the display region DA, the peripheral region PFA having a frame shape surrounding periphery of the display region DA, and the plurality of pixels PIX arranged on a matrix form inside the display region DA. The display apparatus DSP1 includes a substrate 10, a controller circuit 5 formed on the substrate 10, and a driver circuit 6 formed on the substrate 10. The substrate 10 is made of, for example, glass or resin. The substrate 10 has a surface 10f and a surface 10b opposite to the surface 10f.

The controller circuit 5 is a controller circuit that controls driving of a display function of the display apparatus DSP1. The controller circuit 5 is, for example, a driver Integrated Circuit (IC) mounted on the substrate 10. In the example shown in FIG. 1, the controller circuit 5 is arranged along one short side of four sides of the substrate 10. In the example of the present embodiment, the controller circuit 5 includes a signal-line driver circuit that drives a wiring (video signal wiring) VL (see FIG. 2) connected to the plurality of pixels PIX. However, a position and a configuration example of the controller circuit 5 are not limited to those of the example shown in FIG. 1, and include various modification examples. For example, in FIG. 1, a circuit substrate such as flexible substrate may be connected to a position illustrated as the controller circuit 5, and the driver IC may be mounted on the circuit substrate. Alternatively, for example, the signal-line driver circuit that drives the wiring VL may be formed separately from the controller circuit 5.

The driver circuit 6 includes a circuit that drives a scan signal line GL (see FIG. 2 described later) of the plurality of pixels PIX. The driver circuit 6 includes a circuit that supplies a reference potential to the LED element mounted on each of the plurality of pixels PIX. The driver circuit 6 drives a plurality of scan signal lines GL, based on a control signal output from the controller circuit 5. In the example shown in FIG. 1, the driver circuit 6 is arranged along each of two long sides of four sides of the substrate 10. However, a position and a configuration example of the driver circuit 6 are not limited to those of the example shown in FIG. 1, and include various modification examples. For example, in FIG. 1, a circuit substrate such as flexible substrate may be connected to a position illustrated as the controller circuit 5, and the controller circuit 5 and the driver circuit 6 may be mounted on the circuit substrate.

Next, with reference to FIG. 2, a circuit configuration example of the pixel PIX will be explained. In FIG. 2, note that four pixels PIX are typically exemplified and illustrated. However, each of the plurality of pixels PIX shown in FIG. 1 includes the same circuit as that of the pixel PIX shown in FIG. 2. A circuit including a switch included in the pixel PIX and the LED element 20 may be referred to as pixel circuit below. The pixel circuit is a circuit of a voltage signal system controlling a light emission state of the LED element 20 in accordance with a video signal Vsg supplied from the controller circuit 5 (see FIG. 1).

As shown in FIG. 2, the pixel PIX includes the LED element 20. The LED element 20 is the above-described micro light emitting diode. The LED element 20 includes an anode electrode 20EA and a cathode electrode 20EK. The cathode electrode 20EK of the LED element 20 is connected to a wiring VSL to which a reference potential (fixed potential) PVS is supplied. The anode electrode 20EA of the LED element 20 is electrically connected to a drain electrode ED of a switching element SW through a wiring 31.

The pixel PIX includes the switching element SW. The switching element SW is a transistor that controls a connection state (ON or OFF state) between the pixel circuit and the wiring VL in response to a control signal Gs. The switching element SW is, for example, a thin film transistor. When the switching element SW is turned ON, the video signal Vsg is input from the wiring VL to the pixel circuit.

The driver circuit 6 includes a shift register circuit, an output buffer circuit and others not illustrated. The driver circuit 6 outputs a pulse in accordance with a horizontal scan start pulse transmitted from the controller circuit 5 (see FIG. 1), and outputs a control signal Gs.

Each of the plurality of scan signal lines GL extends in an X direction. The scan signal line GL is connected to a gate electrode of the switching element SW. When the control signal Gs is supplied to the scan signal line GL, the switching element SW is turned ON to supply the video signal Vsg to the LED element 20.

### <Peripheral Structure of LED Element>

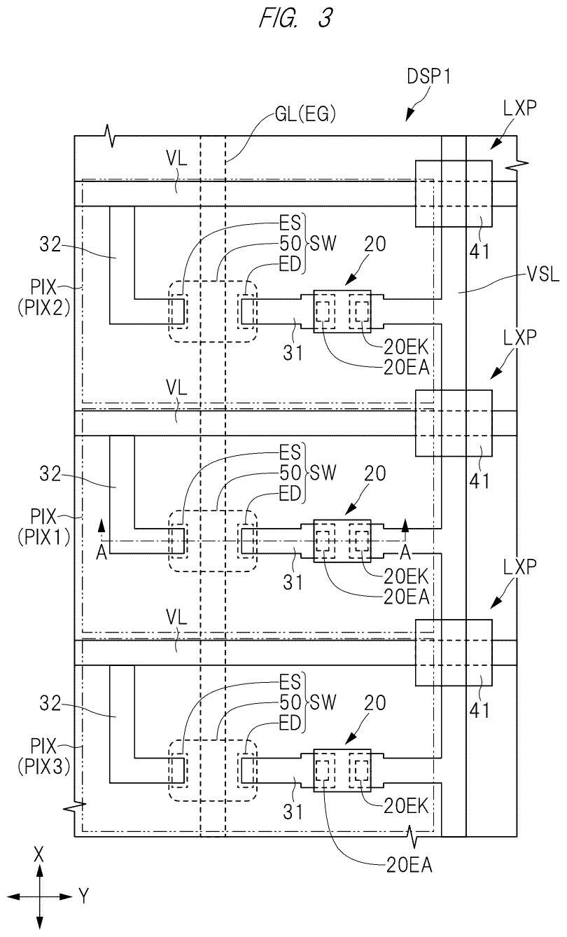

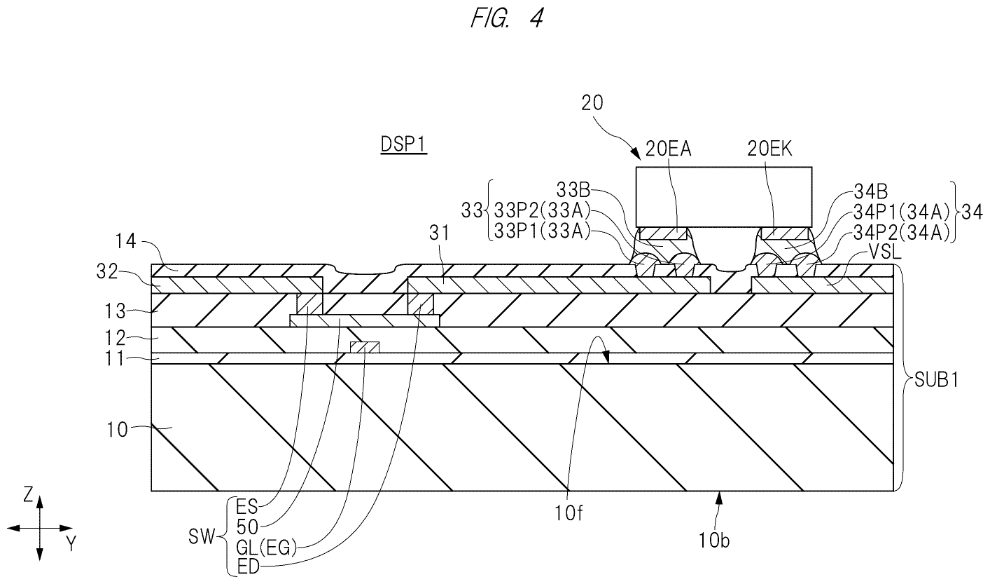

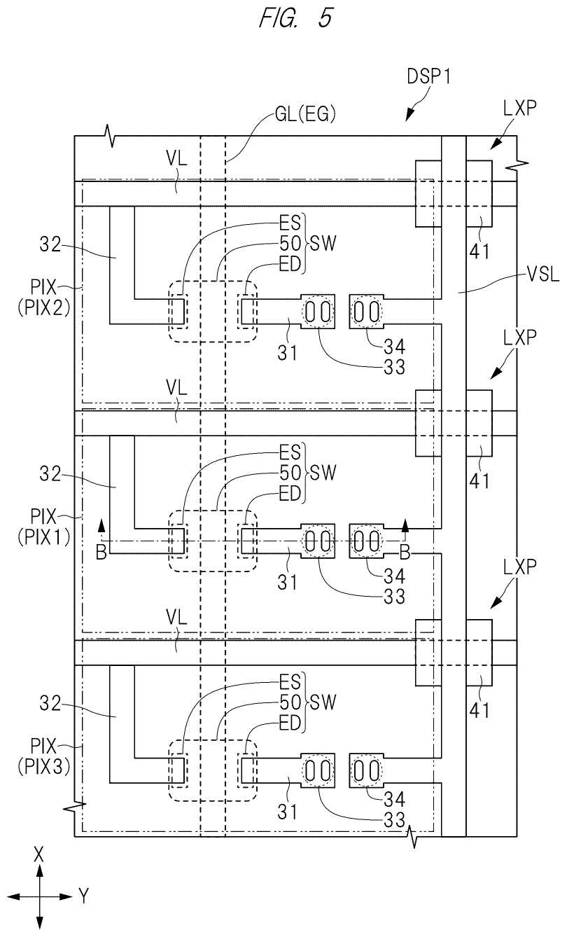

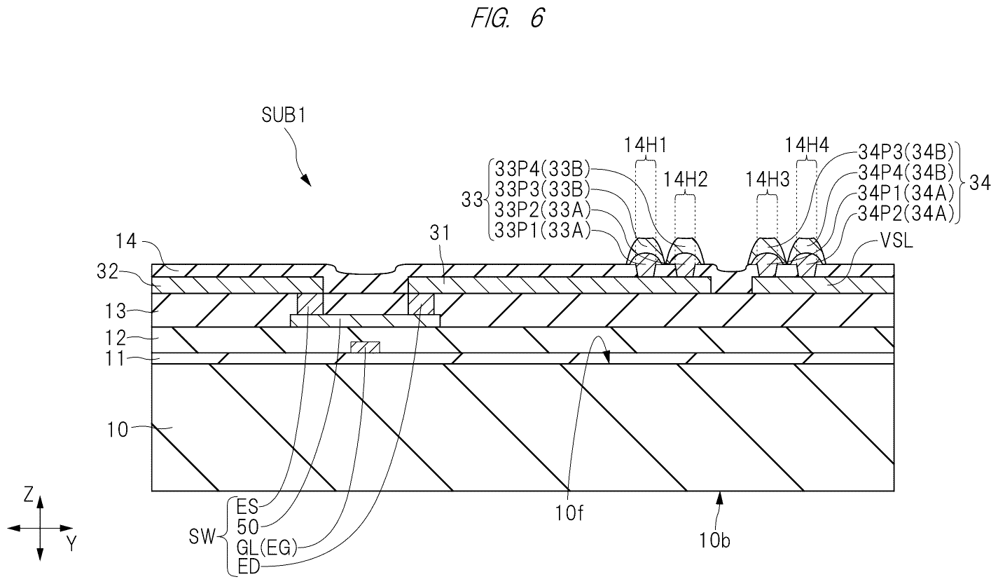

Next, a peripheral structure of the LED element arranged in each of the plurality of pixels PIX shown in FIG. 1 will be explained. FIG. 3 is a perspective enlarged plan view showing an example of the peripheral structure of the LED element arranged in each of the plurality of pixels of the display apparatus shown in FIG. 1. In FIG. 3, illustration of an insulating layer 14 shown in FIG. 4 is omitted. In FIG. 3, outlines of the semiconductor layer, the electrode and the scan signal line are illustrated with a dotted line. FIG. 4 is an enlarged cross-sectional view taken along a line A-A of FIG. 3. FIG. 5 is an enlarged plan view showing a state before mounting of the LED element shown in FIG. 3. FIG. 6 is an enlarged cross-sectional view taken along a line B-B of FIG. 5. FIG. 7 is an enlarged cross-sectional view of vicinity of a connection interface between the wiring and the bump electrode shown in FIG. 4. FIG. 8 is a perspective enlarged plan view showing planar positional relation among a conductor portion containing copper, a wiring and an opening formed in an insulating layer in the bump electrode shown in FIG. 7. In FIG. 8, each of an outline of an opening 14H1, an outline of an opening 14H2, an outline of a portion 33P1 of a conductor portion 33A, an outline of a portion 33P2 of the conductor portion 33A and the wiring 31 is illustrated with a dotted line. In FIG. 8, an outline of the anode electrode 20EA of the LED element 20 is illustrated with a dashed double-dotted line. In FIG. 8, an outline of the conductor portion 33B is illustrated with a solid line. Each of perspective enlarged plane views explained below is illustrated with the same line type as that of FIG. 8.

As shown in FIG. 3, the display apparatus DSP1 includes the plurality of pixels PIX including a pixels PIX1 (in the example shown in FIG. 4, pixels PIX1, PIX2 and PIX3). Each of the plurality of pixels PIX includes the switching element SW, the LED element (light emitting element) 20, the wiring 31 and the wiring 32. Note that the LED element 20 that emits visible light of any one color of, for example, red, green and blue is mounted on each of the pixels PIX1, PIX2 and PIX3, and the switching element SW that drives the LED element 20 is formed. The color display is achieved by control for output and timing of the visible light emitted from the LED elements of the pixels PIX1, PIX2 and PIX3. In a case of combination of the plurality of pixels PIX emitting the visible light of different colors from one another as described above, the pixel PIX for each color may be called sub-pixel, and a set of the plurality of pixels PIX may be called pixel. In the present embodiment, a portion corresponding to this sub-pixel is called pixel PIX.

The wiring 31 is electrically connected to each of the drain electrode ED of the switching element SW and the anode electrode 20EA of the LED element 20. The wiring 32 is connected to the source electrode ES of the switching element SW. In the example shown in FIG. 3, the wiring 32 has a bending structure, and its one end is connected to the source electrode ES of the switching element SW while its other end is connected to the wiring VL. The scan signal line GL is used as the gate electrode EG of the switching element SW.

The display apparatus DSP1 further includes: a wiring VL extending in a Y direction to be over the plurality of pixels PIX (see FIG. 2) and being electrically connected to the wiring 32; and a wiring VSL extending in the X direction crossing (in FIG. 3, being orthogonal to) the Y direction to be over the plurality of pixels PIX and being electrically connected to the cathode electrode 20EK of the LED element 20. The wiring VL and the wiring VSL crosses each other through the insulating layer 41 at a wiring crossing LXP shown in FIG. 3. Since the insulating layer 41 interposes between the wiring VL and the wiring VSL, the wiring VL and the wiring VSL are electrically insulated from each other. Note that layout shown in FIG. 3 is one example, and includes various modification examples. For example, a structure in which the switching element SW includes a not-illustrated gate electrode connected to the scan signal line GL may be exemplified as one modification example relative to FIG. 3. In this modification example, the scan signal line GL may be arranged at a position not overlapping a semiconductor layer 50.

As shown in FIG. 4, the display apparatus DSP1 is an electronic apparatus including the substrate 10 made of glass or resin and the plurality of insulating layers stacked on the substrate 10. The plurality of insulating layers included in the display apparatus DSP1 include an insulating layer 11, an insulating layer 12, an insulating layer 13 and an insulating layer 14 stacked on the substrate 10. The substrate 10 has the surface 10f and the surface 10b opposite to the surface 10f. Each of the insulating layers 11, 12, 13 and 14 is stacked on the surface 10f of the substrate 10.

The switching element SW includes: the insulating layer 12 formed on the substrate 10; the semiconductor layer 50 formed on the insulating layer 12; the drain electrode ED connected to the drain region of the semiconductor layer 50; the source electrode ES connected to the source region of the semiconductor layer 50; and the insulating layer 13 covering the semiconductor layer 50.

The example shown in FIG. 4 is an example of a bottom gate system in which the gate electrode EG is between the semiconductor layer 50 and the substrate 10. In the bottom gate system, a portion of the insulating layer 12, the portion being between the gate electrode EG and the semiconductor layer 50, functions as the gate insulating layer. The insulating layer 12 also functions as a base layer for forming the semiconductor layer 50. Note that a position of the gate electrode EG is not limited to that of the example shown in FIG. 4, and, for example, a top gate system may be applied as a modification example.

Each of the insulating layers 11, 12, 13 and 14 is an inorganic insulating film made of an inorganic material. The material forming each of the insulating layers 11, 12, 13 and 14 is not particularly limited. For example, silicon oxide (SiO₂), silicon nitride (SiN) or others can be exemplified. The semiconductor layer 50 is a semiconductor film in which, for example, a silicon film made of silicon is doped with a P-type or N-type conductive impurity.

Each of the source electrode ES and the drain electrode ED is a contact plug for making electrical contact with either one of the source region and the drain region of the semiconductor layer 50. As a material of the contact plug, for example, tungsten or others can be exemplified. As a modification example relative to FIG. 4, note that a contact hole for exposing the source region and the drain region of the semiconductor layer 50 may be formed in the insulating layer 13, and a part of the wiring 31 and a part of the wiring 32 may be buried inside the contact hole. In this case, the buried parts of the wirings 31 and 32 inside the contact hole are in contact with the semiconductor layer 50, and contact interfaces between the wirings 31 and 32 and the semiconductor layer 50 can be regarded as the drain electrode ED and the source electrode ES.

As shown in FIG. 5, the display apparatus DSP1 includes a plurality of bump electrodes 33 and a plurality of bump electrodes 34 that are orderly arranged in plan view. The bump electrodes 33 and 34 are terminals for mounting the electronic component onto the substrate 10 (see FIG. 4). In the present embodiment, the bump electrodes 33 and 34 are terminals for mounting the LED element 20 shown in FIG. 4. In the example shown in FIG. 4, the bump electrode 33 is connected to the anode electrode 20EA of the LED element 20, and the bump electrode 34 is connected to the cathode electrode 20EK of the LED element 20. As the pair of the bump electrodes 33 and 34, two bump electrodes are adjacent to each other in a region where the LED element 20 (see FIG. 3) is to be mounted.

As exemplified in FIG. 7, the wiring 31 is a stacked film of a conductor layer 30A and a conductor layer 30B. The conductor layer 30A is made of titanium or titanium alloy, and is formed on the insulating layer 13. The conductor layer 30B is made of aluminum or aluminum alloy, and is stacked on the conductor layer 30A. A modification example may include a structure in which the conductor layer 30B made of aluminum or aluminum alloy is sandwiched by the conductor layers 30A made of titanium or titanium alloy.

If the conductor portion 33A of the bump electrode 33 and the conductor portion 34A of the bump electrode 34 shown in FIG. 4 are made of copper or copper alloy, the aluminum film is more advantageous than the titanium film because of providing the higher connection reliability, as the metal film connected to the conductor portion 33A and the conductor portion 34A (the metal film to be the outermost surface of the wiring 31 or the wiring VSL). On the other hand, a surface of the aluminum film is easier to be oxidized than that of the titanium film, and therefore, a step of removing its oxide film is preferably put before forming the conductor portion 33A and the conductor portion 34A. Note that the step of removing the oxide film includes various modification examples, and, for example, a process (that is called a zincate process) of replacing the aluminum oxide film with a zincate film can be exemplified. When this zincate process is applied, a conductor film containing zinc is formed between the conductor layer 30B shown in FIG. 7 and the conductor portion 33A of the bump electrode 33.

As shown in FIG. 7, the bump electrode 33 is connected to the wiring 31 at a position overlapping the opening 14H1 and the opening 14H2 formed in the insulating layer 14, and protrudes from the insulating layer 14. The bump electrode 33 includes the conductor portion 33A made of copper or copper alloy and being connected to the conductor layer 30B of the wiring 31 and the conductor portion 33B made of solder containing tin and being formed on the conductor portion 33A. By the use of the conductor portion 33A made of copper or copper alloy as described above, the electrical property of the bump electrode 33 can be improved.

As the metal material forming the conductor portion 33A, copper or copper alloy can be exemplified as described in the present embodiment. However, various modification examples are applicable. In order to improve the electrical property, the metal material forming the conductor portion 33A is preferably a material having higher electrical conductivity than that of the solder forming the conductor portion 33B. And, in order to avoid the conductor portion 33A from deforming at the time of heating of the bump electrode 33 in the step of the mounting of the LED element 20 shown in FIG. 4, the metal material forming the conductor portion 33A is preferably a material having higher melting point than that of the solder forming the conductor portion 33B.

The conductor portion 33A may be made of a stacked film formed by stacking metal material films of a plurality of types. If a stacked film formed by stacking, for example, a nickel film made of nickel on a copper film made of copper or copper alloy is used as the conductor portion 33A, the surface of the conductor portion 33A can be suppressed from being oxidized.

Incidentally, as shown in FIG. 7, the conductor portion 33A of the bump electrode 33 has a portion 33P1 connected to the wiring 31 at a position overlapping the opening 14H1 formed in the insulating layer 14 and a portion 33P2 connected to the wiring 31 at a position overlapping the opening 14H2 formed in the insulating layer 14. As shown in FIGS. 7 and 8, the conductor portion 33B is not divided into two as different from the conductor portion 33A. The conductor portion 33B is connected to the anode electrode 20EA (see FIG. 7), and is connected to each of the portion 33P1 and the portion 33P2. In the example shown in FIG. 7, the insulating layer 14 is arranged at a position overlapping a part of the conductor portion 33B of the bump electrode 33 (more specifically, between the opening 14H1 and the opening 14H2). The conductor portion 33B is in contact with the insulating layer 14 at a position between the portion 33P1 and the portion 33P2 of the conductor portion 33A.

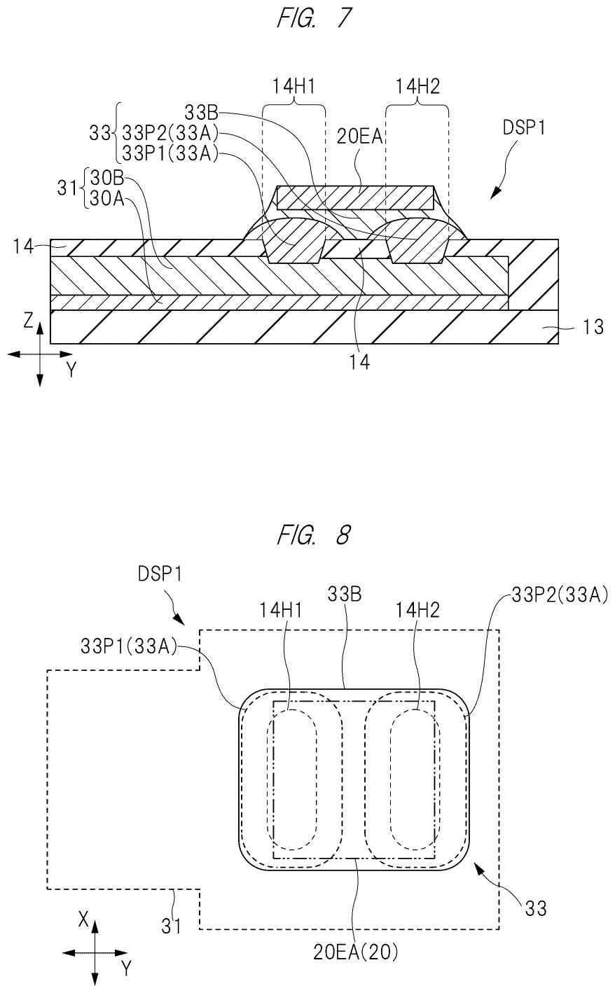

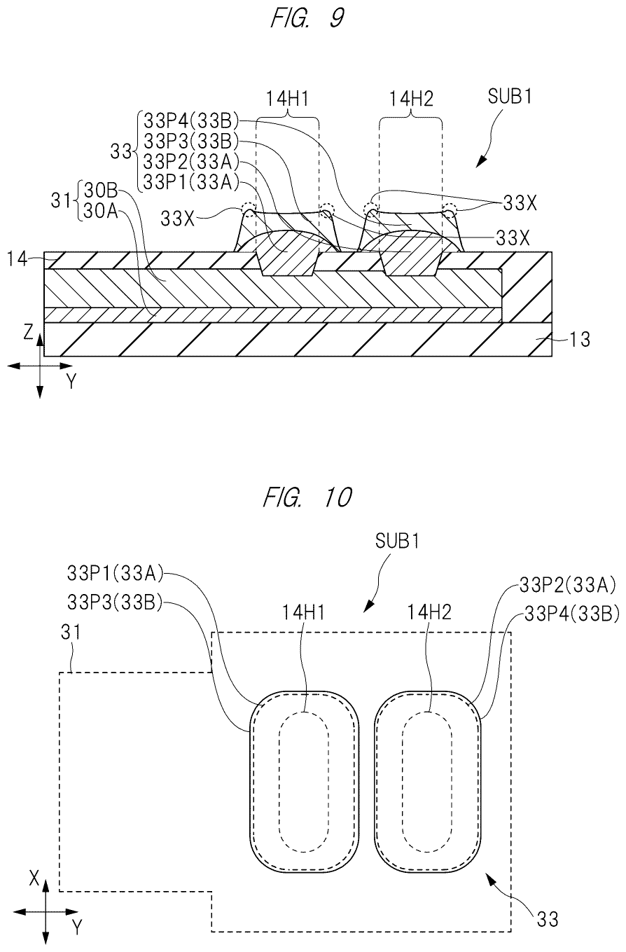

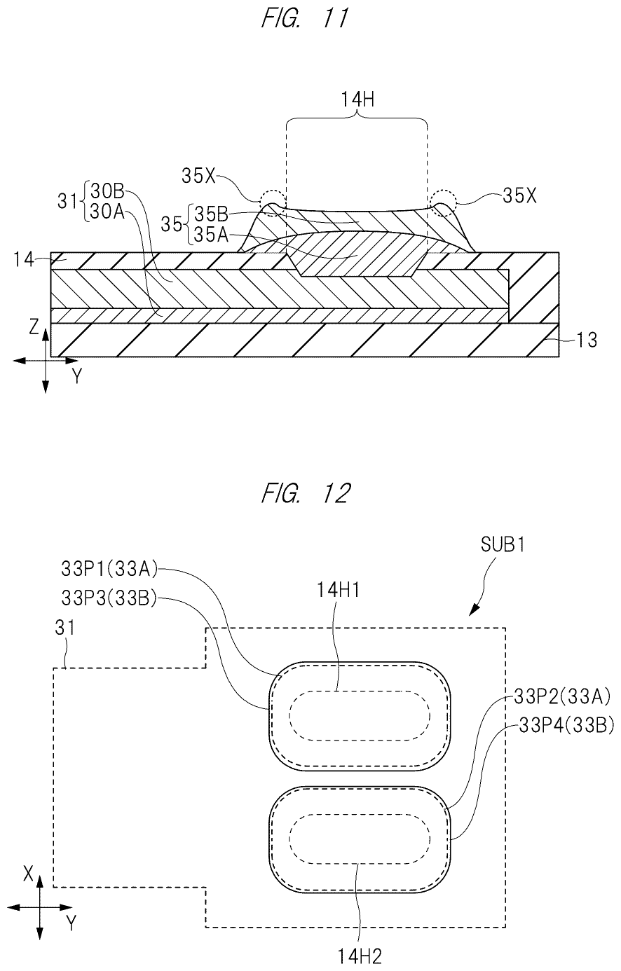

In the present embodiment, since the bump electrode 33 has the structure shown in FIG. 7, the voids (air bubbles) are prevented from being formed between the bump electrode 33 and the anode electrode 20EA. A reason for this will be explained below. FIG. 9 is an enlarged cross-sectional view of vicinity of a connection interface between a wiring and a bump electrode shown in FIG. 6. FIG. 10 is a perspective enlarged plan view showing planar positional relation among a conductor portion containing solder, a wiring and an opening formed in an insulating layer in the bump electrode shown in FIG. 9. FIG. 11 is an enlarged cross-sectional view showing a study example relative to FIG. 9. FIG. 12 is a perspective enlarged plan view showing a modification example relative to FIG. 10.

The bump electrode 33 provided before the mounting of the LED element 20 in the step of manufacturing the display apparatus DSP1 shown in FIG. 4 has the structure as shown in FIGS. 9 and 10. The conductor portion 33A includes the portion 33P1 and the portion 33P2 separating from each other. A portion 33P3 of the conductor portion 33B is stacked on the portion 33P1, and a portion 33P4 of the conductor portion 33B is stacked on the portion 33P2. In the example shown in FIGS. 9 and 10, the portion 33P3 and the portion 33P4 separate from each other. However, as a modification example, the portion 33P3 and the portion 33P4 may be partially coupled with each other.

In a step of connecting the LED element 20 to the bump electrode 33 in the step of manufacturing the display apparatus DSP1 shown in FIG. 4, the bump electrode 33 is heated in a state in which the anode electrode 20EA of the LED element 20 and the bump electrode 33 are in contact with each other. To a heating method, various methods are applicable. For example, the bump electrode 33 can be heated by irradiation of the bump electrode 33 with laser light. By the heating for the bump electrode 33, the solder contained in the conductor portion 33B is melted and deformed. In the present embodiment, the portion 33P3 and the portion 33P4 of the conductor portion 33B shown in FIGS. 9 and 10 are in contact with each other and are unified. And, the solder contained in the conductor portion 33B wetly spreads on a surface of the anode electrode 20EA as shown in FIG. 7, and the anode electrode 20EA and the conductor portion 33A are electrically connected to each other through the conductor portion 33B.

In this case, in the formation of the bump electrode for connecting the anode electrode 20EA shown in FIG. 4, a method of connecting a bump electrode 35 made of one conductor portion 35A and one conductor portion 35B to the anode electrode 20EA (see FIG. 4) as shown in FIG. 11 is considerable as a study example. However, from the studies made by the inventors of the present application, it has been found out that the case of the study example shown in FIG. 11 tends to form a wall portion 35X on an edge of the conductor portion 35B made of solder. The larger an area of the conductor portion 35B in plan view is, the easier formation of a high wall portion 35X is, and the wall portion 35X is formed along the edge of the bump electrode 35 in plan view. A top of center of the bump electrode 35 has a space surrounded by the wall portion 35X. When the anode electrode 20EA shown in FIG. 4 is connected in a state with such a space, it is considered that gas in the space surrounded by the wall portion 35X has no escape region, and remains as voids.

Meanwhile, in the case of the present embodiment, as shown in FIG. 9, the conductor portion 33A includes the portion 33P1 and the portion 33P2 separating from each other. The portion 33P3 of the conductor portion 33B is stacked on the portion 33P1, and the portion 33P4 of the conductor portion 33B is stacked on the portion 33P2. In this case, even if the wall portion 33X is formed on the tops of the portion 33P3 and the portion 33P4 as shown in FIG. 9, a height of the wall portion 33X is lower than that of the wall portion 35X shown in FIG. 11. This is because each length of the portion 33P3 and the portion 33P4 in the Y direction is shorter than a length of the conductor portion 33B in the Y direction as shown in FIG. 11. As described above, even if the wall portion 33X is formed, when its height is low, the gas in the space surrounded by the wall portion 33X is easily discharged to outside.

Further, in the case of the present embodiment as shown in FIG. 9, there is the space between the portion 33P3 and the portion 33P4 of the conductor portion 33B. As shown in FIG. 10, both ends of the space between the portion 33P3 and the portion 33P4 of the conductor portion 33B are opened.

When melting of the solder contained in the bump electrode 33 advances, the portion 33P1, the portion 33P2 and the anode electrode 20EA (see FIG. 7) are unified through the conductor portion 33B as shown in FIGS. 7 and 8. In other words, the display apparatus DSP1 (see FIG. 4) includes the electronic component (LED element 20) including the anode electrode 20EA connected to the bump electrode 33. The conductor portion 33B of the bump electrode 33 is connected to the anode electrode 20EA, and is connected to each of the portion 33P1 and the portion 33P2.

The entirety of the gas in periphery of the conductor portion 33B shown in FIG. 9 is discharged to outside through the space between the portion 33P3 and the portion 33P4 of the conductor portion 33B shown in FIG. 10 or others. Therefore, in the display apparatus provided after the connection between the anode electrode 20EA and the bump electrode 33 as shown in FIG. 7, the voids are difficult to remain between the anode electrode 20EA and the bump electrode 33. In other words, in the case of the present embodiment, the space between the portion 33P3 and the portion 33P4 of the conductor portion 33B can be used as a discharge path of the gas, and therefore, the generation of the voids can be suppressed.

In the example shown in FIG. 10, each of the portion 33P1 and the portion 33P2 has a linear pattern extending in the X direction in plan view. Also, each of the portion 33P3 and the portion 33P4 has a linear pattern extending in the X direction in plan view. Note that the extending direction of each of the portion 33P1 and the portion 33P2 is not limited to the X direction. For example, as shown in a modification example in FIG. 12, each of the portion 33P1 and the portion 33P2 may have a linear pattern extending in the Y direction. If each of the portion 33P1 and the portion 33P2 has the linear pattern as shown in FIGS. 10 and 12, a wetly-spreading direction of the solder contained in the conductor portion 33B and a discharge direction of the gas are easily controlled.

As shown in FIG. 4, the display apparatus DSP1 includes a wiring VSL and a bump electrode 34 connected to the wiring VSL and protruding from the insulating layer 14. The wiring VSL is formed on the substrate 10, separate from the wiring 31, and is covered with the insulating layer 14. The bump electrode 33 and the bump electrode 34 are arranged along the Y direction crossing the X direction (see FIG. 10). In other words, in the example shown in FIG. 10, each of the portion 33P1 and the portion 33P2 extends in the X direction crossing the Y direction that is the arrangement directions of the bump electrode 33 and the bump electrode 34. On the other hand, in the modification example shown in FIG. 12, each of the portion 33P1 and the portion 33P2 extends in the Y direction that is the arrangement directions of the bump electrode 33 and the bump electrode 34.

As shown in the example in FIG. 4, if a separate distance between the anode electrode 20EA and the cathode electrode 20EK is sufficiently large, a risk of short circuit between the bump electrode 33 and the bump electrode 34 is small. However, if the separate distance between the anode electrode 20EA and the cathode electrode 20EK is small, the example shown in FIG. 10 is more preferable in a viewpoint of prevention of the short circuit between the conductor portion 33B of the bump electrode 33 and the conductor portion 34B of the bump electrode 34. In the case of the example shown in FIG. 10, the solder wetly spreads along the X direction, and therefore, a wetly-spread area of the solder in the Y direction is easily controlled. Therefore, even if the separate distance between the anode electrode 20EA and the cathode electrode 20EK is small, the short circuit between these electrodes through the solder contained in the conductor portion 33B of the bump electrode 33 and the conductor portion 34B of the bump electrode 34 can be prevented.

As shown in FIG. 6, note that the bump electrode 34 has the same structure as that of the bump electrode 33. In other words, the bump electrode 34 is made of the same metal material (such as copper or copper alloy) as that of the bump electrode 33, and includes a conductor portion 34A connected to the wiring VSL and a conductor portion 34B made of solder containing tin and arranged on the conductor portion 34A. The conductor portion 34A includes a portion 34P1 connected to the wiring VSL at a position overlapping an opening 14H3 formed in the insulating layer 14 and a portion 34P2 separating from the portion 34P1 and connected to the wiring VSL at a position overlapping an opening 14H4 formed in the insulating layer 14.

FIG. 6 shows a state provided before the connection of the cathode electrode 20EK of the LED element 20 shown in FIG. 4 to the bump electrode 34. Therefore, the conductor portion 34B of the bump electrode 34 includes a portion 34P3 stacked on the portion 34P1 and a portion 34P4 stacked on the portion 34P2. In the example shown in FIG. 6, the portion 34P3 and the portion 34P4 separate from each other. However, as a modification example, the portion 34P3 and the portion 34P4 may be partially connected to each other.

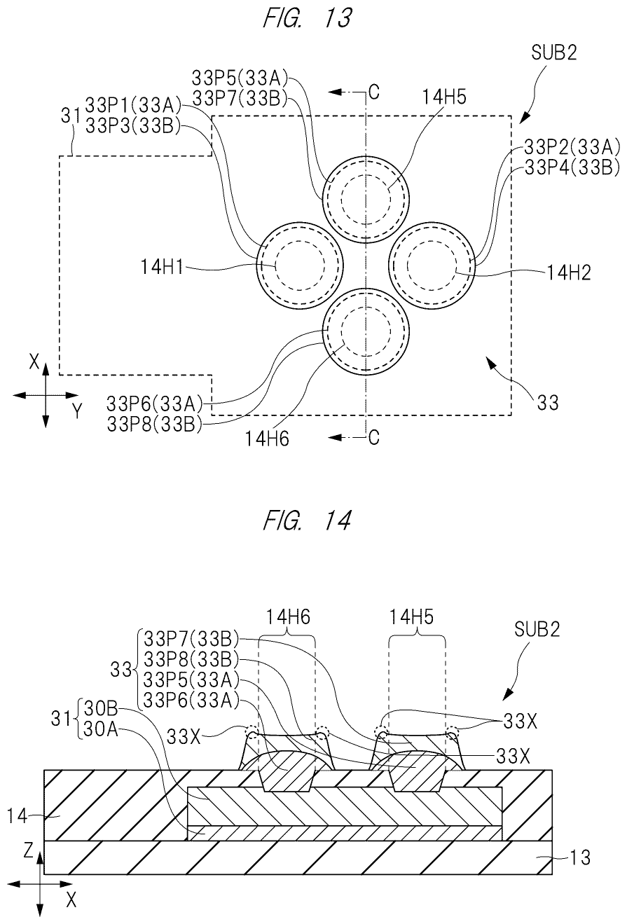

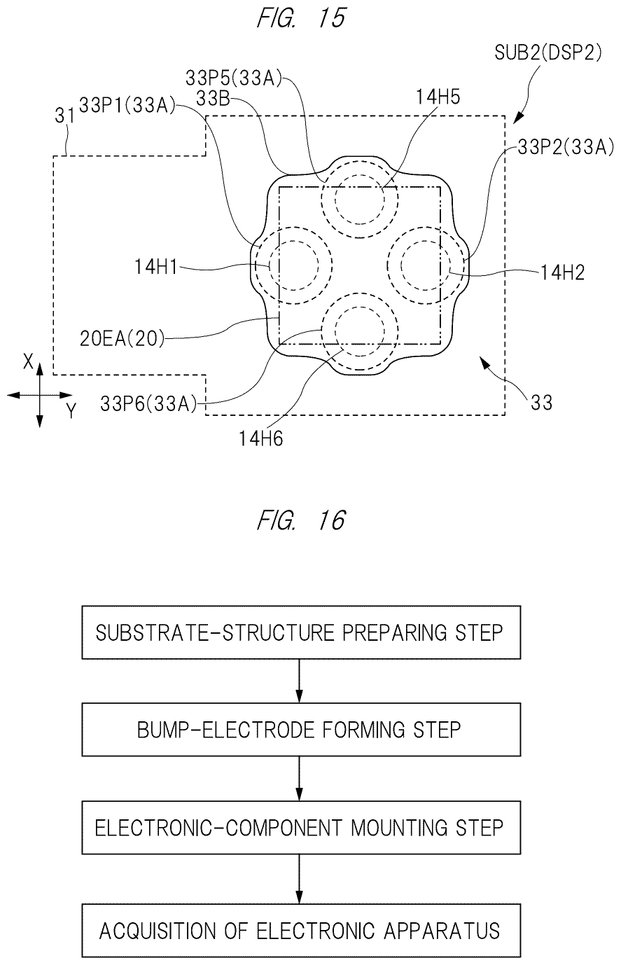

FIG. 13 is a perspective enlarged plan view showing another modification example relative to FIG. 10. FIG. 14 is an enlarged cross-sectional view taken along a line C-C of FIG. 13. FIG. 15 is a perspective enlarged plan view showing a connection state between the anode electrode of the LED element and the bump electrode shown in FIGS. 13 and 14.

FIGS. 13 and 14 show a substrate structure SUB2 according to a modification example relative to the substrate structure SUB1 shown in FIGS. 9 and 10. FIG. 15 shows a display apparatus DSP2 including the LED element 20 shown in FIG. 4 mounted on the bump electrode 33 of the substrate structure SUB2 shown in FIGS. 13 and 14. The modification example shown in FIGS. 13 and 14 is different from the example shown in FIGS. 9 and 10 in the following point. In the modification example, the conductor portion 33A further includes a portion 33P5 separating from the portion 33P1 and the portion 33P2 and connected to the wiring 31 at a position overlapping an opening 14H5 formed in the insulating layer 14. Also, the conductor portion 33A further includes a portion 33P6 separating from the portion 33P1, the portion 33P2 and the portion 33P5 and connected to the wiring 31 at a position overlapping an opening 14H6 formed in the insulating layer 14. As shown in FIG. 13, each of the portion 33P1, the portion 33P2, the portion 33P5 and the portion 33P6 has a circular pattern in plan view.

After the mounting of the LED element 20 shown in FIG. 4, the conductor portion 33B is unified as shown in FIG. 15. In other words, as shown in FIG. 15, the display apparatus further includes the electronic component (LED element 20) including the anode electrode 20EA connected to the bump electrode 33. The conductor portion 33A of the bump electrode 33 is connected to each of the portion 33P1, the portion 33P2, the portion 33P5 and the portion 33P6.

Also in the present modification example, the conductor portion 33A is divided into four. Therefore, when the conductor portion 33B is heated and melted to be unified, respective spaces between the portion 33P1, the portion 33P2, the portion 33P5 and the portion 33P6 function as discharge paths of the gas. As a result, also in the present modification example, the formation of the voids between the anode electrode 20EA and the conductor portion 33B can be prevented.

In the present modification example, in the state provided after the mounting of the LED element 20, the insulating layer 14 is arranged at positions (more specifically, respective positions between the opening 14H1, the opening 14H2, the opening 14H5 and the opening 14H6) overlapping a part of the conductor portion 33B of the bump electrode 33. The conductor portion 33B is in contact with the insulating layer 14 at the respective positions between the portion 33P1, the portion 33P2, the portion 33P5 and the portion 33P6 of the conductor portion 33A.

### <Method of Manufacturing Electronic Apparatus>

Next, as a typical example of a method of manufacturing the electronic apparatus of the present embodiment, a method of manufacturing the display apparatus shown in FIG. 4 will be explained. FIG. 16 is an explanatory diagram showing an example of a step flow of the method of manufacturing the display apparatus according to one embodiment of the electronic apparatus. As shown in FIG. 16, the method of manufacturing the electronic apparatus of the present embodiment includes a substrate-structure preparing step, a bump-electrode forming step and an electronic-component mounting step. If the substrate structure before the mounting of the electronic component is shipped as a semi-manufactured product, note that the electronic-component mounting step can be eliminated.

In the substrate-structure preparing step, the substrate structure SUB1 in the state provided before the formation of the bump electrode 33 shown in FIG. 4 is prepared. In the substrate-structure preparing step, the substrate structure SUB1 including the substrate 10 made of glass or resin, the wiring 31 formed on the substrate 10, and the insulating layer 14 covering the wiring 31 is prepared. The insulating layer 11, the insulating layer 12, the insulating layer 13 and the insulating layer 14 are stacked on the substrate 10, and the wiring 31 is arranged between the insulating layer 13 and the insulating layer 14. The substrate structure SUB1 is mostly covered with the insulating layer 14. The insulating layer 14 includes the opening 14H1 (see FIG. 9) and the opening 14H2 (see FIG. 9) formed at the position overlapping the wiring 31 and the opening 14H3 (see FIG. 6) and the opening 14H4 (see FIG. 6) formed at the position overlapping the wiring VSL.

When the oxide film is formed on each surface of portions of the wiring 31 and the wiring VSL, the portions being exposed from the insulating layer 14, an oxide-film removing step for removing the oxide film may be executed as a preprocess executing the bump-electrode forming step.

Next, in the bump-electrode forming step, the bump electrode 33 and the bump electrode 34 (see FIG. 4) explained with reference to each drawing of FIGS. 4 to 15 are formed. A method of forming the bump electrode 33 connected to the wiring 31 will be explained below as a typical example. Note that the bump electrode 34 connected to the wiring VSL can be formed by the same method explained below.

In the bump-electrode forming step, the conductor portion 33A is formed by an electric plating method in an electrically conducting state of the wiring 31 shown in FIG. 4 (first film-forming step). More specifically, the conductor portion 33A made of copper or copper alloy is selectively formed at the position overlapping the opening 14H1, the position overlapping the opening 14H2 and in periphery of the opening by the electric plating method in the electrically conducting state of the wiring 31. In this case, a copper film (or copper alloy film) can be selectively grown from an exposed surface of the wiring 31. In the present embodiment, the copper film can be selectively grown at a portion of the wiring 31, the portion exposed from the insulating layer 14. Therefore, it is unnecessary to newly prepare a large-scale exposure apparatus such as a large stepper. Note that the electric current can be simultaneously flown in the wiring 31 and the wiring VSL, and therefore, the conductor portion 33A on the wiring 31 and the conductor portion 34A on the wiring VSL can be collectively formed at the same timing.

Next, the conductor portion 33B made of solder containing tin is selectively formed on the conductor portion 33A in the electrically conducting state of the wiring 31 (second film-forming step). Also in the case of the formation of the solder film, by the electric plating method as similar to the case of the formation of the copper film, the solder film is isotropically spread over the surface of the electrically conducting conductor portion 33A to form the conductor portion 33B. By the present step, as shown in FIGS. 9 and 10, the bump electrode 33 including two separate portions can be provided.

In the bump-electrode forming step of the present embodiment, a part of the insulating layer 14 is used as a mask for forming the portion 33P1 and the portion 33P2 of the conductor portion 33A. Therefore, as explained with reference to FIG. 7, the bump electrode 33 having the structure in which the insulating layer 14 is arranged at the position overlapping a part of the conductor portion 33B of bump electrode 33 (more specifically, the position between the openings 14H1 and 14H2).

The substrate structure SUB1 (see FIG. 4) provided before the mounting of the electronic component may be shipped as the semi-manufactured product in some cases. In such a case, the electronic-component mounting step shown in FIG. 16 is eliminated, and the substrate structure SUB1 shown in FIG. 6 undergoes a necessary test and is packed, and then, enters a shipment preparation phase. In other words, by the bump-electrode forming step in FIG. 16, the substrate structure SUB1 functioning as the electronic apparatus can be provided.

Next, in the electronic-component mounting step shown in FIG. 16, after bump-electrode forming step, the bump electrode 33 and the electronic component (the LED element 20 in the example of FIG. 4) are electrically connected to each other as shown in FIG. 4. In the present step, for example, by laser irradiation, the conductor portion 33B and the conductor portion 34B shown in FIG. 6 are melted. In this manner, the bump electrode 33 is connected to the anode electrode 20EA of the LED element 20, and the bump electrode 34 is connected to the cathode electrode 20EK of the LED element 20. Before the present step, note that the solder film may be previously formed in each of the anode electrode 20EA and the cathode electrode 20EK of the LED element 20 shown in FIG. 4. In this case, the conductor portion 33B made of solder and the solder film formed in the electrode can be easily unified, and therefore, the bump electrode 33 and the anode electrode 20EA can be securely connected to each other. The same goes for the bump electrode 34 and the cathode electrode 20EK shown in FIG. 4.

### <Modification Example of Bump Electrode>

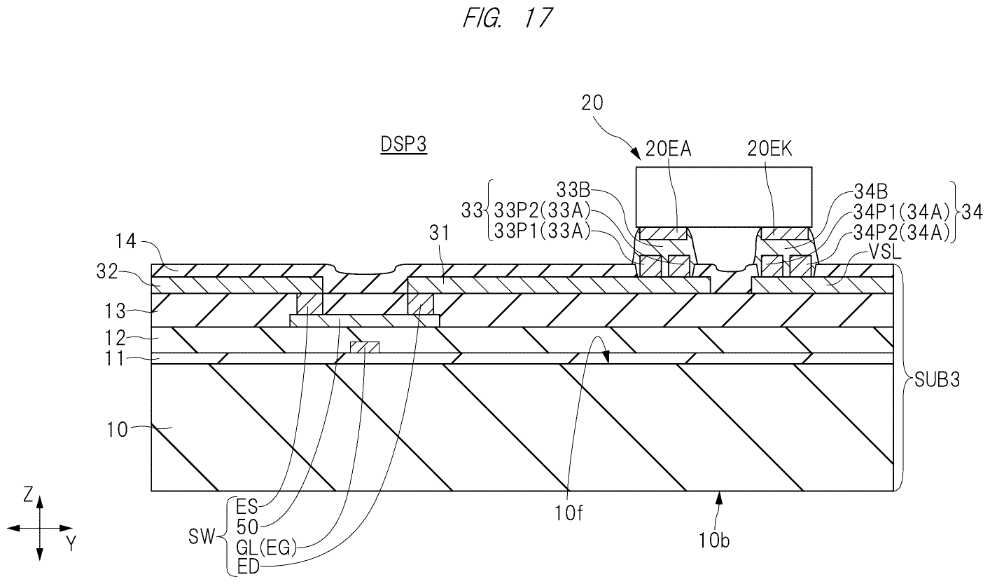

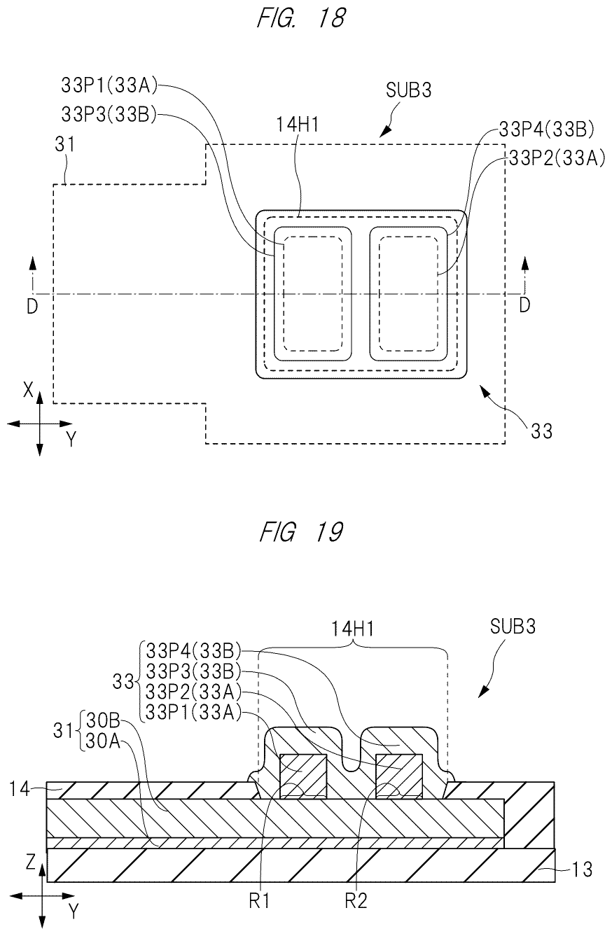

Next, a modification example of the bump electrode will be explained. FIG. 17 is an enlarged cross-sectional view showing a modification example relative to FIG. 4. FIG. 18 is a perspective enlarged plan view showing periphery of the bump electrode in the state provided before the mounting of the LED element shown in FIG. 7. FIG. 19 is an enlarged cross-sectional view taken along a line D-D of FIG. 18.

FIG. 17 shows a display apparatus DSP3 according to a modification example relative to the display apparatus DSP1 shown in FIG. 4. Each of FIGS. 18 and 19 shows a substrate structure SUB3 according to a modification example relative to the substrate structure SUB1 shown in FIGS. 9 and 10.

The display apparatus DSP3 shown in FIG. 17 is different from the display apparatus DSP1 shown in FIG. 4 in the structures of the bump electrode 33 and the bump electrode 34. In the case of the display apparatus DSP3 shown in FIG. 17, the portion 33P1 and the portion 33P2 of the conductor portion 33A separate from each other in one opening 14H1 as shown in FIGS. 18 and 19. Therefore, as shown in FIG. 19, there is no insulating layer 14 between the portion 33P1 and the portion 33P2, the conductor portion 33B containing solder is in contact with the upper surface of the wiring 31 (the exposed surface from the opening 14H1).

The display apparatus DSP3 shown in FIG. 17 and the substrate structure SUB3 included in the display apparatus DSP3 can be expressed as follows. The display apparatus DSP3 that is the electronic apparatus and the substrate structure SUB3 included in the display apparatus DSP3 include the substrate 10, the wiring 31 arranged on the substrate 10, the insulating layer 14 being the inorganic insulating layer made of the inorganic material and covering the wiring 31, and the bump electrode 33 connected to the wiring 31 and protruding from the insulating layer 14. The bump electrode 33 includes the conductor portion 33A made of the first metal material (such as copper or copper alloy) and connected to the wiring 31, and the conductor portion 33B made of the solder containing tin and arranged on the conductor portion 33A. As shown in FIG. 19, the conductor portion 33A includes the portion 33P1 connected to the wiring 31 in a region R1 of the opening 14H1 formed in the insulating layer 14 and the portion 33P2 separating from the portion 33P1 and connected to the wiring 31 in a region R2 of the opening 14H1.

In the bump electrode 33 shown in FIGS. 9 and 10, the conductor portion 33A is formed by the electric plating method in the electrically conducting state of the wiring 31 as described above. In this case, since the insulating layer 14 is used as the mask, the insulating layer 14 remains between the portion 33P1 and the portion 33P2 after the formation of the portion 33P1 and the portion 33P2 of the conductor portion 33A.

On the other hand, the bump electrode 33 shown in FIGS. 18 and 19 is formed by, for example, the following method. That is, a metal film made of copper or copper alloy is formed on the insulating layer 14 and the opening 14H1 of the insulating layer 14. As a film forming method, a sputtering method, a Chemical Vapor Deposition (CVD) method, a panel plating method and others can be exemplified. By such a method, the metal film having a uniform thickness is formed on the insulating layer 14 and the opening 14H1 of the insulating layer 14. Then, a resist mask is formed to cover portions corresponding to the portion 33P1 and the portion 33P2 shown in FIG. 19. For patterning the resist mask, a photosensitive organic film and a photolithography technique using an exposure apparatus are used. Next, in a state in which the portion 33P1 and the portion 33P2 are covered with the resist mask, an etching process is executed to remove an unnecessary portion of the metal film. By the above-described processes, the conductor portion 33A shown in FIG. 19 is formed. After this, as similar to the second film-forming step, the conductor portion 33B made of the solder containing tin is formed by an electric plating method. By the plating process in an electrically conducting state of the wiring 31 shown in FIG. 19, the conductor portion 33B is selectively formed on a portion of the wiring 31, the portion being exposed from the opening 14H1, and the exposed surface of the conductor portion 33A.

In the bump electrode 33 resulted from the above-described processes, a part of the portion 33P3 and a part of the portion 33P4 may be unified as shown in FIG. 19. Note that a space is formed between a top of the portion 33P3 and a top of the portion 33P4.

In the electronic-component mounting step (see FIG. 16) of mounting the LED element 20 shown in FIG. 17, as already explained above, the bump electrode 33 is connected to the anode electrode 20EA of the LED element 20 by the melting of the conductor portion 33B. In the example shown in FIG. 17, the display apparatus DSP3 further includes an electronic component including the anode electrode 20EA connected to the bump electrode 33. The conductor portion 33B of the bump electrode 33 is connected to each of the portion 33P1 and the portion 33P2. In this case, a space between a top of the portion 33P1 and a top of the portion 33P2 functions as the discharge path of the gas. Therefore, also in the present modification example, the formation of the voids between the bump electrode 33 and the anode electrode 20EA shown in FIG. 17 can be prevented.

The bump electrode 33 has been explained above. The bump electrode 34 shown in FIG. 17 also has the same structure as that of the bump electrode 33 shown in FIG. 17.

In the example shown in FIG. 18, each of the portion 33P1 and the portion 33P2 has a linear pattern extending in the X direction in plan view.

As shown in FIG. 17, the conductor portion 33B of the bump electrode 33 is in contact with the wiring 31 between the portion 33P1 and the portion 33P2 of the conductor portion 33A.

As shown in FIG. 17, the display apparatus DSP3 includes a wiring VSL and a bump electrode 34, the wiring VSL being formed on the substrate 10, separating from the wiring 31, and being covered with the insulating layer 14, and the bump electrode 34 being connected to the wiring VSL and protruding from the insulating layer 14. The bump electrode 33 and the bump electrode 34 are arranged along the Y direction crossing the X direction. In other words, each of the portion 33P1 and the portion 33P2 extends in the direction crossing the arrangement directions of the bump electrode 33 and the bump electrode 34 in plan view.

In the example shown in FIG. 18, the solder wetly spreads along the X direction, and therefore, a wetly-spread area of the solder in the Y direction is easily controlled. Therefore, even if the separate distance between the anode electrode 20EA and the cathode electrode 20EK shown in FIG. 17 is small, the short circuit between these electrodes through the solder contained in the conductor portion 33B of the bump electrode 33 and the conductor portion 34B of the bump electrode 34 can be prevented.

Although not illustrated, each of the portion 33P1 and the portion 33P2 shown in FIG. 18 may extend in the Y direction as similar to the modification example explained with reference to FIG. 12. When the separate distance between the anode electrode 20EA and the cathode electrode 20EK shown in FIG. 17 is sufficiently secured, even in the application of the modification example as similar to FIG. 12, the short circuit between these electrodes through the solder contained in the conductor portion 34B can be prevented.

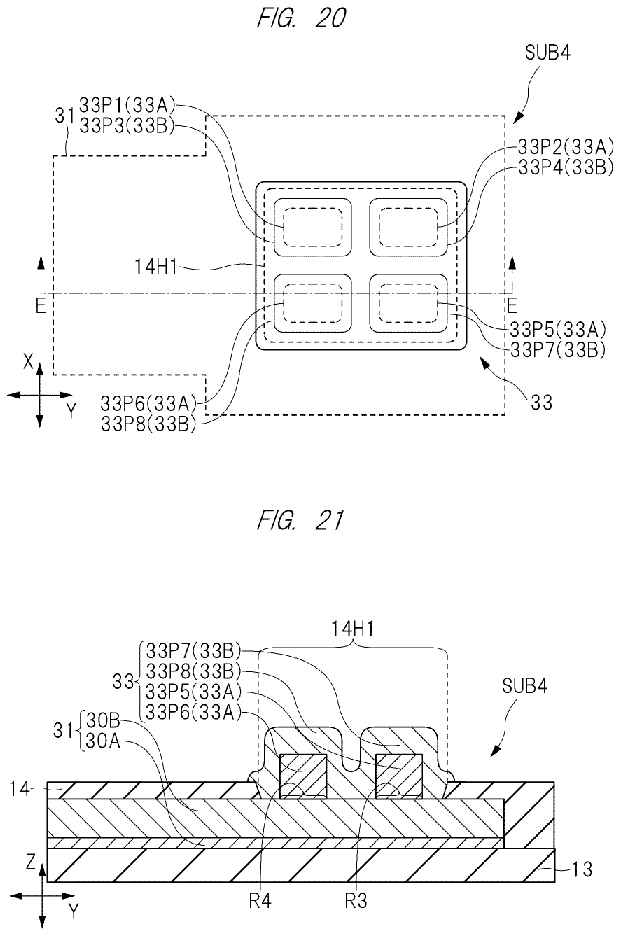

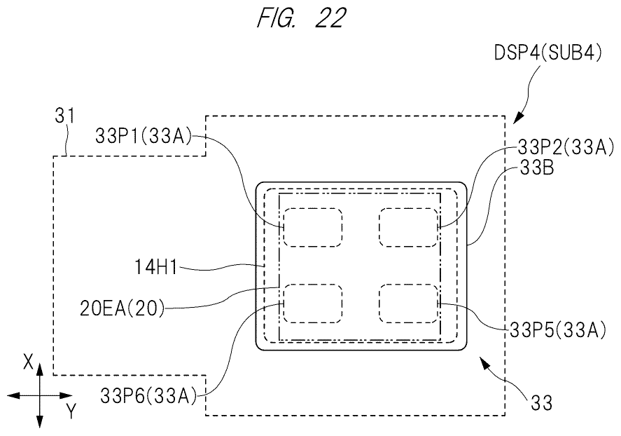

As shown in FIGS. 20 and 21, combination of the structure of the bump electrode 33 explained with reference to FIGS. 13 to 15 with the structure of the bump electrode 33 explained with reference to FIGS. 17 to 19 is applicable. FIG. 20 is a perspective enlarged plan view showing a modification example relative to FIG. 18. FIG. 21 is an enlarged cross-sectional view taken along a line E-E of FIG. 20. FIG. 22 is a perspective enlarged plan view showing a connection state between the anode electrode of the LED element and the bump electrode shown in FIGS. 20 and 21.

Each of FIGS. 20 and 21 shows a substrate structure SUB4 according to a modification example relative to the substrate structure SUB3 shown in FIGS. 18 and 19. FIG. 22 shows a display apparatus DSP4 including the LED element 20 shown in FIG. 17 mounted on the bump electrode 33 of the substrate structure SUB4 shown in FIGS. 20 and 21.

In the bump electrode 33 included in the substrate structure SUB4 that is an electronic apparatus shown in FIG. 17, the conductor portion 33A further includes a portion 33P5 separating from the portion 33P1 and the portion 33P2 and being connected to the wiring 31 in a region R3 (see FIG. 21) of the opening 14H1 and a portion 33P6 separating from each of the portion 33P1, the portion 33P2 and the portion 33P5 and being connected to the wiring 31 in a region R4 (see FIG. 21) of the opening 14H1.

As shown in FIG. 20, each of the portion 33P1, the portion 33P2, the portion 33P5 and the portion 33P6 has a rectangular (quadrangular) pattern in plan view. Note that each portion of the conductor portion 33A shown in FIG. 20 has the quadrangular shape advantageous to the easiness of the etching process. However, as a modification example, each portion may have the circular shape as similar to each portion of the conductor portion 33A shown in FIG. 13, or may have an ellipsoidal shape not illustrated.

Also in the present modification example, parts of the portion 33P3, the portion 33P4, the portion 33P7 and the portion 33P8 are connected to one another. However, the portion 33P1, the portion 33P2, the portion 33P5 and the portion 33P6 separate from one another. Therefore, spaces are formed among tops of the portion 33P3, the portion 33P4, the portion 33P7 and the portion 33P8 of the conductor portion 33B. Each space functions as the discharge path of the gas when the conductor portion 33B and the anode electrode 20EA of the LED element 20 are connected to each other as shown in FIG. 22.

As shown in FIG. 22, the display apparatus DSP4 including the substrate structure SUB4 includes an electronic component including the anode electrode 20EA connected to the bump electrode 33. The conductor portion 33B of the anode electrode 20EA is connected to the anode electrode 20EA, and is connected to each of the portion 33P1, the portion 33P2, the portion 33P5 and the portion 33P6 of the conductor portion 33A.

The embodiments and the typical modification examples have been explained above. However, the above-described technique is applicable to not only the exemplified modification examples but also various modification examples. For example, the above-described modification examples may be combined with one another.

In the scope of the idea of the present invention, various modification examples and alteration examples could have been easily anticipated by those who are skilled in the art, and it would be understood that these various modification examples and alteration examples are within the scope of the present invention. For example, the ones obtained by appropriate addition, removal, or design-change of the components to/from/into each of the above-described embodiments by those who are skilled in the art or obtained by addition, omitting, or condition-change of the step to/from/into each of the above-described embodiments are also within the scope of the present invention as long as they include the idea of the present invention.

The present invention is applicable to an electronic apparatus such as a display apparatus.

What is claimed is:

1. An electronic apparatus comprising:
a first substrate;
a first wiring arranged on the first substrate;
a first insulating layer being an inorganic insulating layer made of an inorganic material and covering the first wiring; and
a first bump electrode being connected to the first wiring and protruding from the first insulating layer,
wherein the first bump electrode includes:
a first conductor portion being made of a first metal material and being connected to the first wiring; and
a second conductor portion being made of solder containing tin and being arranged on the first conductor portion,
the first conductor portion includes:
a first portion being connected to the first wiring at a position overlapping a first opening formed in the first insulating layer; and
a second portion separating from the first portion and being connected to the first wiring at a position overlapping a second opening formed in the first insulating layer.

2. The electronic apparatus according to claim 1,
wherein each of the first portion and the second portion has a linear pattern extending in a first direction in plan view.

3. The electronic apparatus according to claim 2 further comprising:
a second wiring being formed on the first substrate, separating from the first wiring, and being covered with the first insulating layer; and
a second bump electrode being connected to the second wiring and protruding from the first insulating layer,
wherein the first bump electrode and the second bump electrode are arranged along a second direction crossing the first direction.

4. The electronic apparatus according to claim 1 further comprising
an electronic component including a first electrode connected to the first bump electrode,
wherein the second conductor portion of the first bump electrode is connected to each of the first portion and the second portion.

5. The electronic apparatus according to claim 4,
wherein the first insulating layer is arranged between the first portion and the second portion of the second conductor portion of the first bump electrode.

6. The electronic apparatus according to claim 1,
wherein the first conductor portion further includes:
a third portion separating from the first portion and the second portion and being connected to the first wiring at a position overlapping a third opening formed in the first insulating layer; and
a fourth portion separating from the first portion, the second portion and the third portion and being connected to the first wiring at a position overlapping a fourth opening formed in the first insulating layer.

7. The electronic apparatus according to claim 6,
wherein each of the first portion, the second portion, the third portion and the fourth portion has a circular pattern in plan view.

8. The electronic apparatus according to claim 7 further comprising
an electronic component including a first electrode being connected to the first bump electrode,
wherein the second conductor portion of the first electrode is connected to the first electrode and is connected to each of the first portion, the second portion, the third portion and the fourth portion.

9. The electronic apparatus according to claim 1 further comprising:
a second wiring being formed on the first substrate, separating from the first wiring, and being covered with the first insulating layer; and
a second bump electrode being connected to the second wiring and protruding from the first insulating layer,
wherein the second bump electrode includes:
a fifth conductor portion being made of the first metal material and being connected to the second wiring; and
a sixth conductor portion being made of solder containing tin and being arranged on the fifth conductor portion, and
the fifth conductor portion further includes:
a fifth portion being connected to the second wiring at a position overlapping a fifth opening formed in the first insulating layer; and
a sixth portion separating from the fifth portion and being connected to the second wiring at a position overlapping a sixth opening formed in the first insulating layer.

10. An electronic apparatus comprising:
a first substrate;
a first wiring arranged on the first substrate;
a first insulating layer being an inorganic insulating layer made of an inorganic material and covering the first wiring; and
a first bump electrode being connected to the first wiring and protruding from the first insulating layer,
wherein the first bump electrode includes:
a first conductor portion being made of a first metal material and being connected to the first wiring; and
a second conductor portion being made of solder containing tin and being arranged on the first conductor portion,
the first conductor portion includes:
a first portion being connected to the first wiring in a first region of a first opening formed in the first insulating layer; and
a second portion separating from the first portion and being connected to the first wiring in a second region of the first opening.

11. The electronic apparatus according to claim 10,
wherein each of the first portion and the second portion has a linear pattern extending in a first direction in plan view.

12. The electronic apparatus according to claim 11 further comprising:
a second wiring being formed on the first substrate, separating from the first wiring, and being covered with the first insulating layer; and
a second bump electrode being connected to the second wiring and protruding from the first insulating layer,
wherein the first bump electrode and the second bump electrode are arranged along a second direction crossing the first direction.

13. The electronic apparatus according to claim 10 further comprising
an electronic component including a first electrode being connected to the first bump electrode,
wherein the second conductor portion of the first bump electrode is connected to each of the first portion and the second portion.

14. The electronic apparatus according to claim 10,
wherein the second conductor portion of the first bump electrode is in contact with the first wiring between the first portion and the second portion of the first conductor portion.

15. The electronic apparatus according to claim 10,
wherein the first conductor portion further includes:
a third portion separating from the first portion and the second portion and being connected to the first wiring in a third region of the first opening; and
a fourth portion separating from the first portion, the second portion and the third portion and being connected to the first wiring in a fourth region of the first opening.

16. The electronic apparatus according to claim 15 further comprising
an electronic component including a first electrode being connected to the first bump electrode,
wherein the second conductor portion of the first electrode is connected to the first electrode, and is connected to each of the first portion, the second portion, the third portion and the fourth portion.
